(19) United States
(12) Patent Application Publication
(10) Pub. No.: US 2003/0231779 A1
(43) Pub. Date: Dec. 18, 2003

(54) Method and apparatus for applying audible sound frequency modulated electrical signal

(76) Inventor: Webster Billington, Sun City, CA (US)

Correspondence Address: CHRISTILE, PARKER & HALE, LLP, P.O. BOX 7068, PASADENA, CA, 91109-7068, US

(21) Appl. No.: 10/208,481

(22) Filed: Jul. 30, 2002

Related U.S. Application Data
(63) Continuation-in-part of application No. 10/172,544, filed on Jun. 14, 2002.

(51) Int. Cl. H03G 3/00; H04B 3/00

(52) U.S. Cl. 381/77; 381/61

(57) ABSTRACT

A method of enhancing the well being of a living organism is provided. An electrical signal is modulated at audible sound frequency. The modulated electrical signal is amplified and applied on the living organism in a non-audible manner. The modulated electrical signal can also be applied to organic products such as fruits, vegetables, fresh meat, dairy products, flowers, and the like, and perishable medical products to extend their shelf life and/or delay deterioration with little or no refrigeration.

### CROSS-REFERENCE TO RELATED APPLICATION(S)

This application is a continuation-in-part (CIP) of U.S. patent application Ser. No. 10/172,544 entitled “Method and Apparatus for Applying Audible Sound Frequency Modulated Electrical Signal” filed Jun. 14, 2002, the contents of which are fully incorporated by reference herein.

### FIELD OF THE INVENTION

The present invention is related to application of signals modulated at audible frequencies, and particularly to application of audible sound frequency modulated electrical signal to enhance the well being of living organisms and other organic matter.

### BACKGROUND

In historical applications of audible sound frequencies to the area of agriculture, the sounds have been applied through acoustical speaker systems. Starting with the work of Dr. T. C. N Singh at Amanalai University in Southern India in the early 1950's and extending to the present day, extensive work has been carried out by many researchers on the effects of musical sounds applied through acoustical speakers on various forms of plant life.

It has been shown that application of music stimulates higher production of oxygen, as much as sixty (60) to a hundred percent. Since the plants' output of oxygen is directly proportional to the food manufactured by it, the stimulated plants are able to synthesize a larger amount of nourishment than the conventional plants. The beneficial effects include earlier sprouting, larger plants, and substantially increased yield.

One great disadvantage of applying acoustic sound from the speakers to soil is the deafening noise, which is ear shattering to those near it. To mitigate the undesirable effect of loud noise, ways to apply sound to soil in a quieter manner have been explored. For example, attempts have been made to reduce the noise by burying the speakers underground to eliminate most of the noise. However, it is desirable to reduce the noise beyond that achievable through burying the speakers or other devised noise reduction schemes.

Therefore, it is desirable to develop a method and apparatus for applying audible sound frequencies to the soil without the undesirable effect of noise generated therefrom.

### SUMMARY

In an exemplary embodiment according to the present invention, a method of enhancing the well being of a living organism is provided. The method includes: taking an electrical signal modulated at audible sound frequency; amplifying the modulated electrical signal; and applying the amplified electrical signal on the living organism in a non-audible manner.

In another exemplary embodiment according to the present invention, an apparatus for applying audible sound frequency modulated electrical signal to enhance the well being of a living organism. The apparatus includes: a signal source for generating the audible sound frequency modulated electrical signal; an amplifier for amplifying the audible frequency-modulated electrical signal; and output circuitry for receiving the amplified audible sound frequency modulated electrical signal and for applying the amplified audible sound frequency modulated electrical signal to the living organism.

In yet another exemplary embodiment according to the present invention, a method of preserving organic products such as food products including fruits, vegetables, fresh meat, dairy products, and the like, and flowers is provided. The method includes: generating an electrical signal modulated in the audible sound frequency range; amplifying the modulated electrical signal; and applying the amplified electrical signal on the organic products.

In still another exemplary embodiment according to the present invention, a method of aerating water is provided. The method includes: generating an electrical signal modulated at audible sound frequency; amplifying the modulated electrical signal; and applying the amplified electrical signal to a body of water.

### BRIEF DESCRIPTION OF THE DRAWINGS

These and other aspects of the invention may be understood by reference to the following detailed description, taken in conjunction with the accompanying drawings, wherein:

FIG. 1 is a block diagram of a system for applying audible sound frequency modulated electrical signal in an exemplary embodiment according to the present invention;

FIG. 2 is a schematic diagram for exemplary output circuitry for the system of FIG. 1;

FIGS. 3A and 3B illustrate a physical embodiment of the exemplary output circuitry of FIG. 2;

FIG. 4 is another view of the physical embodiment of FIG. 3;

FIG. 5 illustrates the physical embodiment of FIG. 3 enclosed in a can;

FIG. 6 is a schematic diagram for another exemplary output circuitry for the system of FIG. 1;

FIG. 7 is a schematic diagram for an exemplary amplifier for the system of FIG. 1; and

FIG. 8 is a solid state audio output transformer in another embodiment according to the present invention.

### DETAILED DESCRIPTION

In an exemplary embodiment according to the present invention, musical compositions are applied to soil as audible sound frequency modulated electrical signals. In other embodiments, other patterns of audible frequencies may be used. The audible sound frequency as used herein may also be referred to as an audible frequency or an audible sonic frequency. These audible sound frequencies are applied in a non-acoustic (i.e., silent) manner to soil to beneficially accelerate plant growth. They may also be applied to harvested fruits, vegetables, fresh meat, dairy products, flowers, and/or other organic products that are subject to spoilage, to extend their shelf life and/or delay deterioration without a need for refrigeration or with reduced refrigeration. Further, the audible sound frequencies may be applied to pharmaceutical products such as perishable medical products including penicillin and vaccines. The term “Agronosonics” has been coined to describe these applications of audible sound frequencies to the various areas of agriculture.

The “audible sound frequencies are the frequencies”that can be heard by a normal human ear and range from 16 to 20 vibrations or cycles per second (Hz) for the very low sounds to 16000 to 20000 vibrations or cycles per second for the very high-pitched sounds. As a matter of interest, the ranges of sound, radio and light frequencies are summarized below in Table 1:

TABLE 1
Frequency range for different types of signals

| | |
|---|---|
| Infra-Sound | 0-15 Hz |
| Audible-Sound | 16-20,000 Hz |
| Ultra-Sound | Above 20,000 Hz |
| AM Radio | 550,000-1,700,000 Hz |
| FM Radio | 88,000,000-108,000,000 Hz |
| Light | 400 million MHz-750 million MHz |

“Infra” and “Ultra” sound frequencies, as shown in Table 1 above, are those frequencies below and above, respectively, the range of hearing of the human auditory system. They are known as “silent” sound. Both of these sonic frequency ranges can have very destructive effects on organic tissue as they develop internal molecular friction and heat. For example, ultra sonic, which is used in the medical field, must be carefully controlled because of the heat generated. In contrast, audible sound frequencies typically produce no thermal temperature increases.

In contrast to the audible application of sound frequencies to plants as conventionally done, a method and apparatus in an exemplary embodiment according to the present invention applies sound frequencies in an inaudible manner directly to the soil. In other words, the system of the present invention uses a high-powered amplifier to inject the sound into the soil in a non-acoustic manner.

In the exemplary embodiment, molecular propagation is used to apply non-acoustic signal modulated at audible sound frequency throughout the soil. Using molecular propagation, the signal modulated in the audible sound frequency range is transmitted through molecular structure of matter (which may be solid or liquid) rather than through air. In the exemplary embodiment, the propagation of the non-acoustic signal modulated at audible sound frequencies may be carried out through water, moist application pads, or the moisture in the soil. It may be noted that speed of sound in water (1480 meters per second (m/s)) is more than four times the speed of sound in air (344 m/s at 21° C.).

The exemplary embodiment of the present invention therefore produces beneficial effects similar to the acoustical system without the audible noise side effects. In addition, the exemplary embodiment provides an ability to produce these beneficial effects under adverse farming conditions. The non-acoustic signal modulated at audible sound frequency may also be referred to as an audible sound frequency vibration controlled energy. When the non-acoustic signal modulated at audible sound frequency is applied to human being or animals, it may also be referred to as bio-electricity.

In an exemplary embodiment according to the present invention, a repeating tape of 2 to 5 minutes in length provides the sonic input to an “agronosonic stimulator,” which transmits the sonic stimulation into the soil in a continuous manner. When one envisions the music emanating from 100 instruments in a symphony orchestra each playing at different sonic frequencies, he can then imagine the true potential power and energy available in the multiple release effect of these many frequencies.

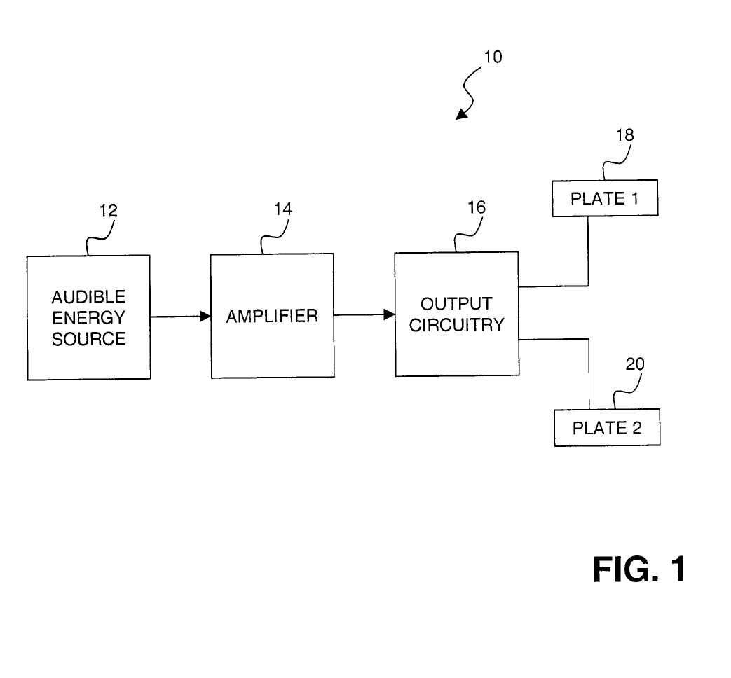

FIG. 1 is a block diagram of a system 10 for applying audible sound frequency modulated electrical signal in an exemplary embodiment according to the present invention. The system 10 may also be referred to as an audible sound frequency stimulator or as an agronosonic stimulator. When the system 10 is applied to a human being or an animal, it may also be referred to as a biosonic stimulator.

The system 10 includes an audible energy source 12, an amplifier 14, output circuitry 16, a plate 1 (18) and a plate 2 (20). Those skilled in the art would appreciate that systems for applying audible sound frequency modulated electrical signal in other embodiments may also have other components, instead of or in addition to the components illustrated in FIG. 1.

The audible energy source 12 produces electrical signal modulated at a frequency of audible sound, which may be between the frequencies of 16 Hz through 20,000 Hz. The audible energy source 12, for example, may include, but are not limited to, a radio, a cassette player, an MP3 player, a CD player, a computer, an integrated circuit (IC) chip, or any other device that is capable of generating an audible sound frequency modulated electrical signal that can be listened to, for example, using a speaker. The audible sound frequency may represent music, speech, or any other audible sound. For example, the audible frequency generated by the audible energy source may repeatedly generate signals representing a musical piece or a portion thereof. Alternately, random sound patters could be used.

In an exemplary embodiment, a banjo music, for example, an instrumental music entitled “Yours” by Eddy Peabody may be used to generate the audible sound frequency modulated non-acoustic signal. This and other musical compositions or portions thereof may be applied to generate an audible sound frequency modulated signal, which may be replayed continuously in a camatic manner.

The audible energy source 12, for example, may be coupled to the amplifier 14 over a co-axial cable or any other suitable electrical wiring known to those skilled in the art. In other embodiments, the audible energy source may be remotely linked to the amplifier 14 using radio frequency or other suitable remote communication methods known to those skilled in the art.

The audible frequency is then amplified by the amplifier 14 and provided to the output circuitry 16. The amplified modulated electrical signal is then provided to the plates 1 and 2 (18, 20) for application in exemplary embodiments according to the present invention. The plates 1 and 2 may also be referred to as antennas. When the plates 1 and 2 are arrayed in a predetermined angle (e.g., 180 degrees) with respect to one another, a null between the signals emanating from the plates 1 and 2 may occur.

When the plates 1 and 2 (18, 20) are applied to a living organisms, e.g., plants, human beings, animals, etc., the system 10 enhances or promotes well being of these living organisms. Further, when the plates 1 and 2 (18, 20) are applied to harvested fruits, vegetables, fresh meat, dairy products, flowers, etc., the system 10 has a preserving effect.

For example, the plates 1 and 2 (18, 20) may be applied to soil for enhanced plat growth, to a human being or an animal for therapeutic purposes, to a fruit or a vegetable to preserve them, and/or to a body of water to aerate it. The plates 1 and 2 (18, 20) may have other beneficial applications as well. When the plates 1 and 2 (18, 20) are applied to the soil, they may be separated by a predetermined range of distances, which may be between 30 m and 60 m. The distance range may depend on one or more of desired output power, desired coverage area, type of soil (e.g., sandy v. clay), pH of soil, etc.

The output of the audible energy source 12 may be in analog or digital format. When the audible energy source 12 outputs a digital audio signal, for example, the system 10 may include a digital amplifier and/or a digital-to-analog converter (DAC) to generate an electrical signal modulated at audible sound frequencies.

The audible energy source 12, the amplifier 14 and the output circuitry 16 may be supplied with power in ac (alternating current) form from, for example, an electrical outlet. The power may also be supplied using a suitable battery. In other embodiments, the system 10 may include solar cells or panels that are capable of converting sunlight into electrical energy used by the system. This way, the system 10 may be self-contained during its operation without the need for any man-supplied energy.

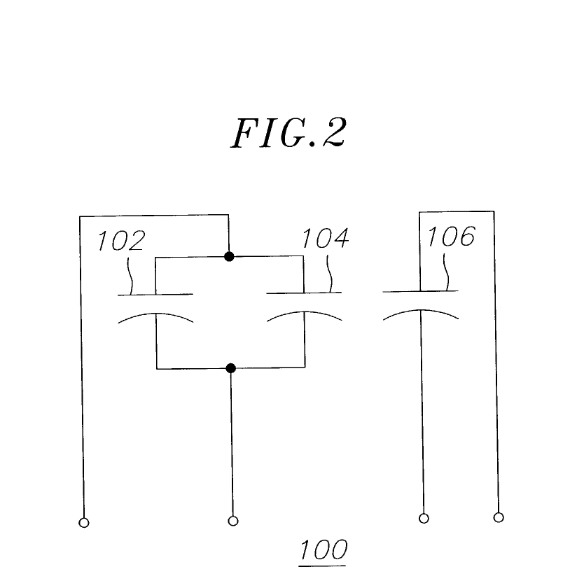

FIG. 2 is a schematic diagram for exemplary output circuitry 100, which may be used as the output circuitry 16 of FIG. 1. The output circuitry 100 includes three capacitors 102, 104 and 106, which may be blocking capacitors. The capacitors 102 and 104 are coupled in parallel, and may be applied, for example, at a positive terminal of the amplifier, such as the amplifier 14 of FIG. 1. The capacitor 160 may be applied, for example at a negative terminal of the amplifier, such as the amplifier 14 of FIG. 1. The capacitors, for example, may have a capacitance of 0.25 micro farad (μf) each. In other embodiments, the capacitors may have other capacitance values. In still other embodiments, different number of capacitors may be used. The energy dissipation in vacuum tubes of the amplifier 14 is approximately 100 watts (25 watts per tube). In other examples, the energy dissipation in the vacuum tubes may be more or less than 100 watts.

The positive and negative terminals, for example, may represent left and right channels of a stereo system. In other embodiments, the negative terminal of the amplifier may comprise ground. In still other embodiments, the positive and negative terminals may represent a pair of differential signals, each modulated at audible sound frequency. In other embodiments, the capacitors 102 and 104 may be coupled to the negative terminal while the capacitor 106 may be coupled to the positive terminal.

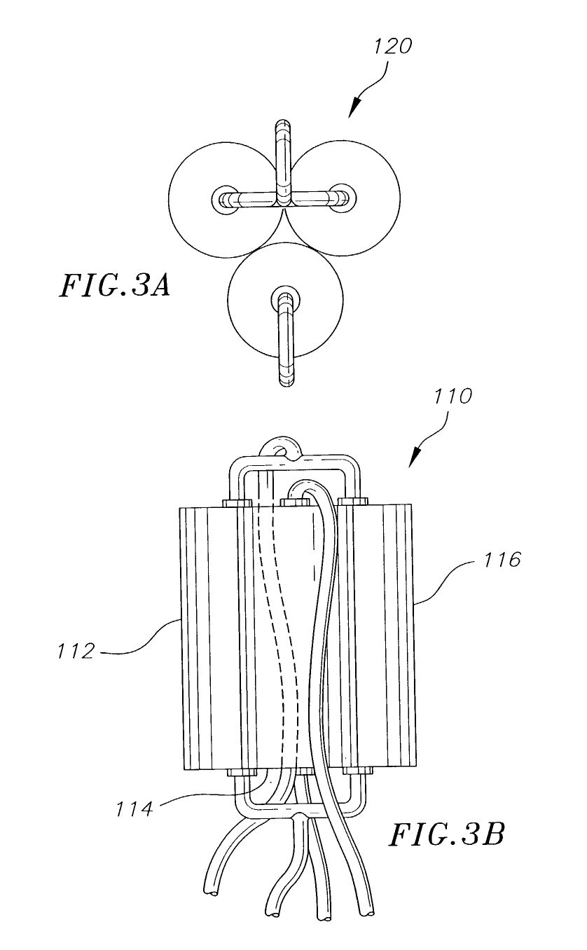

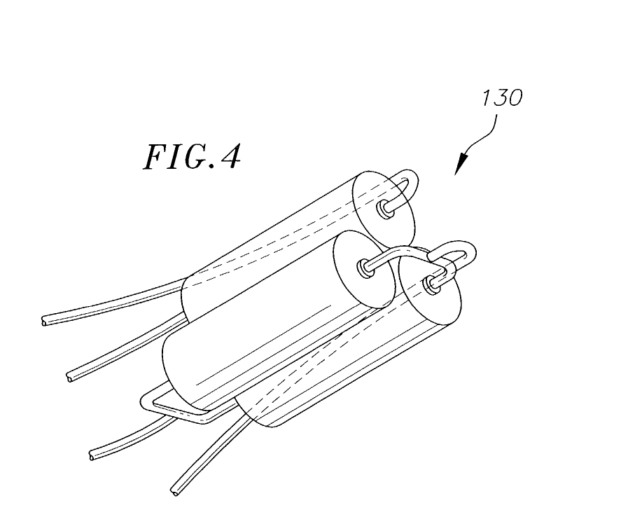

FIGS. 3A and 3B illustrate a physical embodiment of the exemplary output circuitry of FIG. 2. The side view 110 of FIG. 3B illustrates three capacitors 112, 114 and 116. A top view 120 illustrates that two of the capacitors are coupled together while the third capacitor is not coupled to them. It can be seen from the side view 110 and the top view 120 that the terminals of the capacitors 112 and 116 are coupled together in parallel. FIG. 4 illustrates another view 130 of the three capacitors 112, 114 and 116.

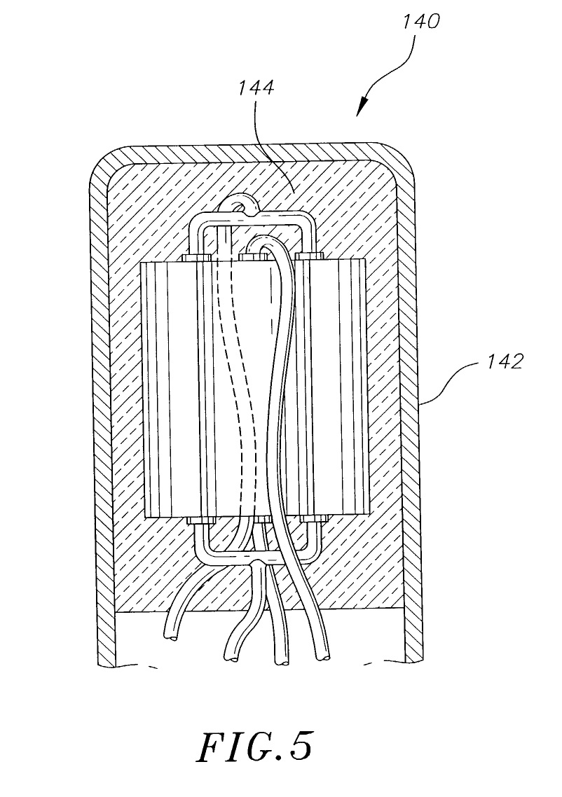

FIG. 5 illustrates a side view 140 of the physical embodiment of FIG. 3 enclosed in a can 142. The can 142, for example, may be made of metal. The can may also provide capacitance. The capacitors in the can 142, for example, may be held in place by applying and curing epoxy 144 in the can 142. In other embodiments, other types of capacitors may be used. Further in other embodiments, material other than epoxy may be used to hold the capacitors in place.

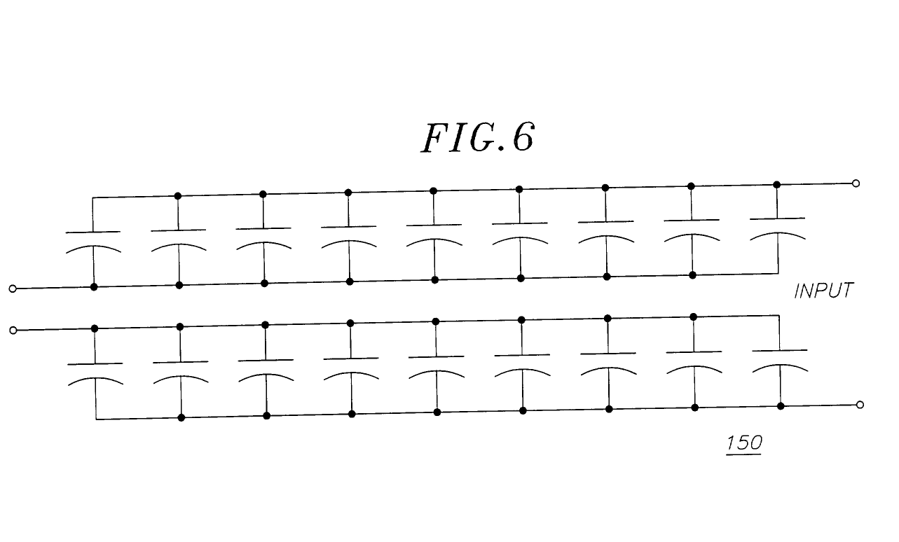

FIG. 6 is a schematic diagram for another exemplary output circuitry 150 for the system of FIG. 1. Output circuitry for coupling to each of positive and negative terminals of the amplifier in this embodiment includes nine (9) capacitors. In other embodiments, the number of capacitors may be more or less than nine. The capacitors used in the output circuitry 150 may be blocking capacitors or any other capacitors known to those skilled in the art.

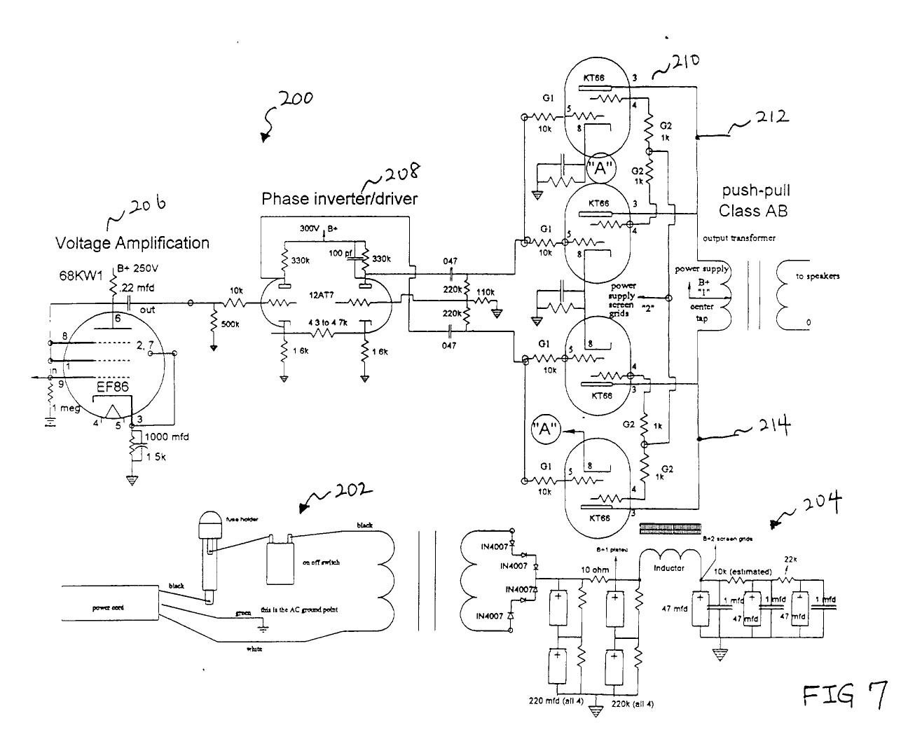

FIG. 7 is a schematic diagram for an exemplary amplifier 200 for the system of FIG. 1. In the amplifier 200, power input circuitry 202 receives input power through a power cord, for example. Supplied power is transformer coupled to power distribution circuitry 204, which is used to apply power to other components of the amplifier 200. In other embodiments, the input power may be supplied by one or more batteries. In still other embodiments, solar energy may be converted to electrical power to supply the input power.

The audible sound frequency modulated electrical signal is applied first at a voltage amplification stage 206. The amplified signal is then inverted in a phase inverter/driver stage 208. Finally, the inverted signal is applied to an output stage 210, which includes a number of vacuum tubes arranged in a push-pull class AB configuration for driving the output circuitry, such as the output circuitry 16 of FIG. 1. The output of the amplifier 200 in an exemplary embodiment should provide a voltage signal of at least 100 volts peak-to-peak (Vpp) for application to soil to enhance plant growth.

The amplifier 200 of FIG. 1 is provided for illustrative purposes only. Those skilled in the art would appreciate that any suitable audio amplifier known to those skilled in the art may be used instead. Further, those skilled in the art would appreciate that the amplifier does not require any output transformers since the amplified signals are tapped directly, for example, at output leads 212 and 214, and coupled to the output circuitry.

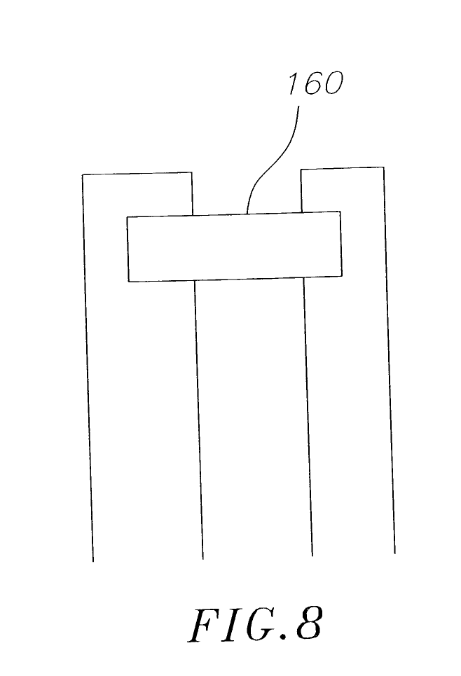

FIG. 8 is a solid state audio output transformer 160 in another embodiment according to the present invention. When the audible sound frequency modulated electrical signal is a digital signal, for example, the audio output transformer 160 may be used as output circuitry instead of the output circuitry including a number of capacitors, for example, of FIGS. 2 and 6. Further, when the audible sound frequency modulated electrical signal is a digital signal, the analog amplifier, such as the amplifier 200 of FIG. 7 may not be needed. Instead, a digital amplifier may be used to increase the signal strength. In other embodiments, digital and analog circuitry for generating respective signals modulated at audible sound frequency may be included in the same housing.

Returning now to FIG. 1, the plates 1 and 2 (18, 20) may be applied to soil (ground) in order to effect plant growth that may require less water. The inventor has also found that the application of these signals to the soil may also result in cooler temperature for the soil.

In an exemplary embodiment according to the present invention, the audible sound frequency stimulation may be applied in a controlled manner, in which a segment of musical frequencies of a pre-determined length of time (1 minute to 3 minutes) is repeatedly played continuously.

It can be demonstrated that plant life can absorb and transmit the audible sound energy from the system in an exemplary embodiment according to the present invention, which may be referred to as an agronosonic stimulator. This may be demonstrated on broad leaf plants or melons as the musical sounds, which are being applied in a non-acoustic (e.g., silent) manner by the agronosonic stimulator, may be heard by human ears when they are drawn out of the surface of the plant or melon. For example, the surface of the leaves or the melon may be stimulated (e.g., by “massaging” or “caressing” with hand) to draw out audible sound. When the audible sound frequency vibration controlled energy is applied non-acoustically to human beings, similar stimulation may be applied to the human beings (e.g., on the back) to draw out audible sound.

An exemplary embodiment of the present invention may be applied to preservation of organic products such as fruits, vegetables, fresh meat, dairy products, flowers, and the like. By applying the output (i.e., audible sound energy) of the exemplary embodiment intermittently to a watermelon, for example, the watermelon may be preserved without deteriorating, for example, nine months or longer. The exemplary embodiment may also be applied to dried fruits such as raisins and dried figs to reduce mold as well as to replace refrigeration, and could be applied to other organic products that are subject to spoilage.

When applied to water, an exemplary embodiment according to the present invention may have an effect of preventing its stagnation, and may also have a cooling effect on water. This may be applied to a fish tank to prevent stagnation of water as well as to do away with requirements for aeration of water to provide oxygen thereto.

Further, bacterial growth may be retarded in living organisms (e.g., human beings or animals) and/or organic matter by applying the stimulator of the present invention. One byproduct of the application of the exemplary embodiment according to the present invention may be hydrogen peroxide (H₂O₂), which may be generated along with oxygen. The preservation effect in exemplary embodiments of the present invention may at least be partly attributable to H₂O₂, which may operate as a germicide. For example, the H₂O₂ may prevent deterioration of organic matter by killing bacteria and/or other micro organisms. By killing bacteria, the exemplary embodiment of the present invention may also enhance the immune system of human beings, plants and/or animals.

An exemplary embodiment according to the present invention may also be applied to a human being or an animal for therapeutic and or organ-regeneration purposes. In this application, the present invention may be referred as a biosonic frequency controlled stimulator or a biosonic stimulator. This embodiment uses controlled non-acoustic audible sound frequencies to induce beneficial stimulation, activation and circulation when applied to organic bodies. Further, as discussed above, bacterial growth in living organisms (e.g., human beings or animals) may be retarded through application of the biosonic frequency controlled stimulator.

Although this invention has been described in certain specific embodiments, many additional modifications and variations would be apparent to those skilled in the art. It is therefore to be understood that this invention may be practiced otherwise than as specifically described. Thus, the described embodiments of the present invention should be considered in all respects as illustrative and not restrictive, the scope of the invention to be determined by the appended claims and their equivalents.

I claim:

1. A method of enhancing the well being of a living organism, the method comprising:
taking an electrical signal modulated at audible sound frequency;
amplifying the modulated electrical signal; and
applying the amplified electrical signal on the living organism in a non-audible manner.

2. The method of claim 1, wherein the audible sound frequency comprises frequency spectrum from 16 Hz through 20,000 Hz.

3. The method of claim 1, wherein the electrical signal represents music.

4. The method of claim 1, wherein the living organism is a plant, and applying comprises applying the amplified electrical signal into soil on which the plant has been planted.

5. The method of claim 1, wherein the living organism is a human being or an animal, and applying comprises applying the amplified electrical signal through said human being or animal, thereby generating corresponding bio-electricity within said human being or animal.

6. The method of claim 1, wherein the amplified electrical signal comprises a differential signal pair, and applying the amplified electrical signal comprises applying first and second signals of the differential signal pair separated by a predetermined distance into soil.

7. An apparatus for applying audible frequency-modulated electrical signal to enhance well being of a living organism, the apparatus comprising:
a signal source for generating the audible sound frequency modulated electrical signal;
an amplifier for amplifying the audible sound frequency modulated electrical signal; and
output circuitry for receiving the amplified audible sound frequency modulated electrical signal and for applying the amplified audible frequency-modulated electrical signal to the living organism in a non-audible manner.

8. The apparatus of claim 7, wherein the signal source comprises one selected from a group consisting of a radio, a cassette player, an MP3 player, a CD player, integrated circuit chip, a DVD player and a computer.

9. The apparatus of claim 7, wherein the output circuitry comprises a number of capacitors, each capacitor having first and second terminals, wherein the output of the amplifier is applied at the first terminals of the capacitors, and ground is applied to the second terminals of the capacitors.

10. The apparatus of claim 7, wherein the audible frequency modulated electrical signal comprises a differential pair of signals.

11. The apparatus of claim 7, wherein the audible sound frequency modulated electrical signal comprises a pair of stereo signals.

12. A method of preserving organic products or pharmaceutical products, the method comprising:
generating an electrical signal modulated at audible sound frequency;
amplifying the modulated electrical signal; and
applying the amplified electrical signal on said organic products or pharmaceutical products.

13. The method of claim 12, wherein the audible sound frequency comprises frequency spectrum from 16 Hz through 20,000 Hz.

14. The method of claim 12, wherein the electrical signal represents music.

15. The method of claim 12, wherein the electrical signal comprises a differential signal pair, and applying the electrical signal comprises applying first and second signals of the differential signal pair on said organic products or pharmaceutical products.

16. The method of claim 12, wherein the electrical signal comprises a pair of stereo signals, and applying the electrical signal comprising applying left and right signals of the stereo signal pair on said organic products or pharmaceutical products.

17. The method of claim 12, wherein the organic products comprise at least one selected from a group consisting of fruits, vegetables, fresh meat, dairy products, dried fruits and flowers.

18. The method of claim 12, wherein the pharmaceutical products comprise perishable medical products.

19. A method of aerating water, the method comprising:
generating an electrical signal modulated at audible sound frequency;
amplifying the modulated electrical signal; and
applying the amplified electrical signal to a body of water.

20. The method of claim 19, wherein the body of water comprises a fish tank.

21. The method of claim 4, wherein the amplified electrical signal has a peak-to-peak voltage (Vpp) of at least 100 volts.
